(19) United States
(12) Patent Application Publication
(10) Pub. No.: US 2025/0096176 A1
(43) Pub. Date: Mar. 20, 2025

(54) PACKAGING STRUCTURE AND PACKAGING METHOD

(71) Applicant: JCET Management Co., LTD., Shanghai (CN)

(72) Inventor: Cheng YANG, Shanghai (CN)

(21) Appl. No.: 18/822,376

(22) Filed: Sep. 2, 2024

(30) Foreign Application Priority Data
Sep. 20, 2023 (CN) 202311220431.4

(51) Int. Cl. H01L 23/00; H01L 23/498; H01L 25/16

(52) U.S. Cl. CPC H01L 24/16; H01L 23/49827; H01L 25/167; H01L 2224/16225; H01L 2924/38

(57) ABSTRACT

A packaging structure includes an intermediary board including opposed a first bonding surface and a second bonding surface, one or more device chips bonded on the first bonding surface of the intermediary board, and an interconnection chip bonded on the second bonding surface of the intermediary board. The intermediary board includes a plurality of interconnection unit areas, and the adjacent interconnection unit areas are spaced apart from each other. An interconnection structure is formed within the interconnection unit area. The device chips are electrically connected to the interconnection structures. The interconnection chip is disposed on the intermediary board between the adjacent interconnection unit areas and electrically connected to the interconnection structures of the adjacent interconnection unit areas.

### CROSS-REFERENCE TO RELATED APPLICATIONS

This application claims the benefit of priority to Chinese Application No. 202311220431.4, filed on Sep. 20, 2023, which is hereby incorporated by reference in its entirety.

### TECHNICAL FIELD

The present disclosure relates to the field of semiconductor packaging, and in particular to a packaging structure and a packaging method.

### BACKGROUND

The rise and development of new technologies, such as the internet of things (IoTs), big data, and artificial intelligence (AI) have driven exponential growth of computing demand, and High-Performance Computing (HPC), which faces massive computing and frequent data access, is gradually entering a bottleneck period. Traditional HPC uses tens of thousands of processors to sequentially construct modules, casings, racks, and even systems from chips. On the one hand, it occupies a large area and is difficult to dissipate heat, which is far from suitable for the development needs of a series of emerging devices, such as wearable and mobile communications; on the other hand, as Moore's Law approaches physical limits, achieving performance doubling through characteristic dimensions shrinkage is unsustainable.

System on Wafer (SOW) emerges because of demand. This technology abandons the application of substrate in traditional solutions. Connectors and power modules are directly welded on the processor wafer, and the interconnections between the processors and between the processor and the peripheral modules are directly achieved by using wafer-level Redistribution Layer (RDL) technology. At the same time, it also has the advantages of wafer-level integration, such as low-delay inter-chip communication, high bandwidth density, and low power delivery network (PDN) impedance. Also, the wafer is directly attached to the heat dissipation module, thereby effectively solving the heat dissipation problem.

### SUMMARY

The present disclosure provides a packaging structure, including an intermediary board, comprising opposed a first bonding surface and a second bonding surface, the intermediary board including a plurality of interconnection unit areas, the adjacent interconnection unit areas being spaced apart from each other, and an interconnection structure being formed within the interconnection unit area; one or more device chips, bonded on the first bonding surface of the intermediary board, the device chips being electrically connected to the interconnection structures; and an interconnection chip bonded on the second bonding surface of the intermediary board, the interconnection chip being disposed on the intermediary board between the adjacent interconnection unit areas and electrically connected to the interconnection structures of the interconnection unit areas.

The present disclosure also provides a packaging method, including providing a packaging module, the packaging module including an intermediary board, including opposed a first bonding surface and a second bonding surface, the intermediary board including a plurality of interconnection unit areas, the adjacent interconnection unit areas being spaced apart from each other, and an interconnection structure being formed within the interconnection unit area; one or more device chips bonded on the first bonding surface of the intermediary board and electrically connected to the interconnection structures; and bonding an interconnection chip on the second bonding surface of the intermediary board, the interconnection chip disposed located on the intermediary board between the adjacent interconnection unit areas and electrically connected to the interconnection structures of the interconnection unit areas.

### BRIEF DESCRIPTION OF THE DRAWINGS

FIGS. 1 and 2 are structural schematic diagrams of a packaging structure, according to some aspects of the present disclosure.

FIGS. 3 and 4 are structural schematic diagrams of another packaging structure, according to some aspects of the present disclosure.

FIGS. 5 and 6 are structural schematic diagrams of still another packaging structure, according to some aspects of the present disclosure.

FIGS. 7-13 are structural schematic diagrams of a packaging method, according to some aspects of the present disclosure.

FIGS. 14 and 15 are structural schematic diagrams of another packaging method, according to some aspects of the present disclosure.

FIGS. 16 and 17 are schematic diagrams of still another packaging method, according to some aspects of the present disclosure.

FIG. 18 is a flowchart of a packaging method, according to some aspects of the present disclosure.

### DETAILED DESCRIPTION

The specific embodiments of the present disclosure are described in detail below in conjunction with the accompanying drawings. In detailing the embodiments of the present disclosure, the schematic diagrams will not be locally enlarged according to the general scale for the convenience of illustration, and the schematic diagrams are only examples, which should not limit the scope of protection of the present disclosure herein. In addition, the three-dimensional spatial dimensions of length, width, and depth should be included in the actual production.

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be disposed between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnects are formed) and one or more dielectric layers.

It should be noted that the terms “comprising,” “including,” and “having,” and their variations, referred to in the present disclosure are intended to cover non-exclusive inclusion. The terms “first,” “second,” etc., are used to distinguish between similar objects and need not be used to describe a specific order or sequence unless the context clearly indicates that the data used in this way can be interchanged in appropriate circumstances. In addition, the embodiments and the features in the embodiments in the present disclosure may be combined with each other without conflict. Furthermore, in the above explanation, descriptions of well-known components and techniques have been omitted to avoid unnecessarily confusing the concepts of the present disclosure. In the various embodiments below, each embodiment focuses on the differences from other embodiments, and the same/similar parts between various embodiments can be referenced to (or referred to) each other.

As can be seen from the Background, the performance of the packaging structures in SOW needs to be improved. The technical solutions of the present disclosure have at least the following advantages.

In order to solve the technical problems, some aspects of the present disclosure provide a packaging structure. The packing structure includes an intermediary board including a plurality of interconnection unit areas, and the adjacent interconnection unit areas are spaced apart from each other. One or more device chips are bonded on the first bonding surface of the intermediary board, and the device chips are electrically connected to the interconnection structure. Interconnection chips are bonded on the second bonding surface of the intermediary board, and the interconnection chips are located on the intermediary board between the adjacent interconnection unit areas and electrically connected to the interconnection structure of the adjacent interconnection unit areas, thereby achieving a global interconnection of the intermediary board through the interconnection structure and the interconnection chips, and thus enabling the electrical connection between device chips, and also facilitating a reduction in the process requirements and process difficulty of forming the intermediary board, as well as enabling high-density interconnections, and optimizing the packaging process and packaging performance.

In order to solve the technical problems, some aspects of the present disclosure provide a packaging method. In the packaging method, the packaging module includes an intermediary board and one or more device chips. The intermediary board includes a plurality of interconnection unit areas, and the adjacent interconnection unit areas are spaced apart from each other. One or more device chips are bonded on the first bonding surface of the intermediary board, and the device chips are electrically connected to the interconnection structure. Interconnection chips are bonded on the second bonding surface of the intermediary board, and the interconnection chips are located between the adjacent interconnection unit areas and electrically connected to the interconnection structure of the adjacent interconnection unit areas, thereby achieving a global interconnection of the intermediary board through the interconnection structure and the interconnection chips, and thus enabling the electrical connection between device chips, and also facilitating a reduction in the process requirements and process difficulty of forming the intermediary board, as well as enabling high-density interconnections, and optimizing the packaging process and packaging performance.

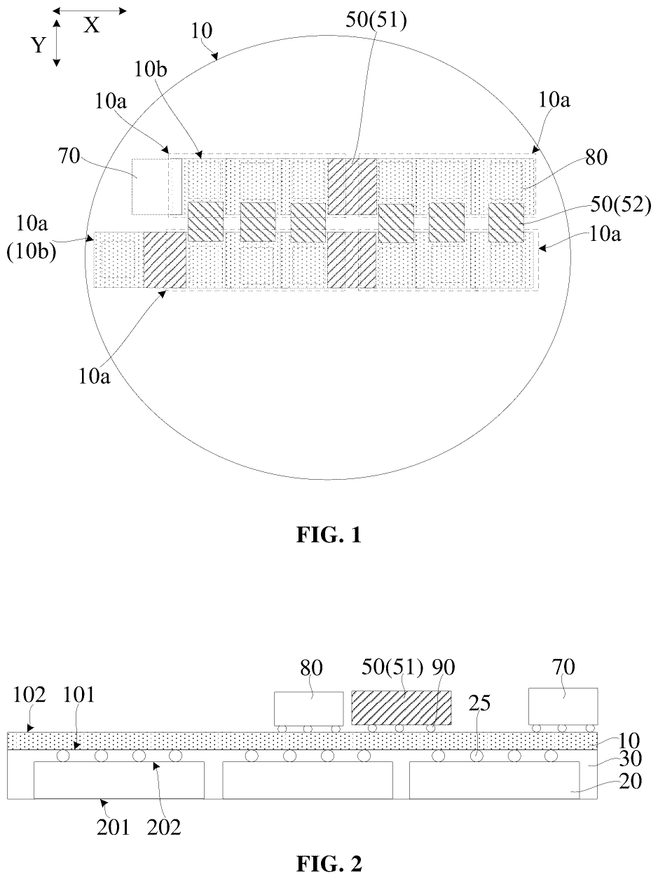

In order to make the above objects, features and advantages of the embodiments of the present disclosure more obvious and understandable, the specific embodiments of the present disclosure are described below in detail in conjunction with the accompanying drawings. FIGS. 1 and 2 are structural schematic diagrams according to an embodiment of the packaging structure of the present disclosure. FIG. 1 is a top view, and FIG. 2 is a cross-sectional view corresponding to FIG. 1.

In the present embodiment, the packaging structure includes an intermediary board 10 including opposed a first bonding surface 101 and a second bonding surface 102. The intermediary board 10 includes a plurality of interconnection unit areas 10a, and the adjacent interconnection unit areas 10a being spaced apart from each other. An interconnection structure is formed within the interconnection unit area 10a. The packaging structure also includes one or more device chips 20 bonded on the first bonding surface 101 of the intermediary board 10. The device chips 20 are electrically connected to the interconnection structures. The packaging structure further includes an interconnection chip 50 bonded on the second bonding surface 102 of the intermediary board 10. The interconnection chip 50 is disposed on the intermediary board 10 between the adjacent interconnection unit areas 10a and electrically connected to the interconnection structures of the interconnection unit areas 10a.

The intermediary board 10 is configured to achieve the interconnection between the device chips 20. The interconnection between the device chips 20 is achieved by the intermediary board 10, which is conducive to shortening the interconnection distance between the device chips 20 and improving the efficiency and stability of information transmission.

The first bonding surface 101 is configured to bond one or more device chips 20, and the second bonding surface 102 is configured to subsequently bond the interconnection chips.

The interconnection unit area 10a is configured to form an interconnection structure. For example, the interconnection structure is configured to achieve interconnection between the device chips 20.

In the present embodiment, adjacent interconnection unit areas 10a are spaced apart. That is, the interconnection structures within adjacent interconnection unit areas 10a are spaced apart, and electrical connection between the interconnection structures of the adjacent interconnection unit areas 10a is achieved by the interconnection chips 50. Thus, in the process of forming the intermediary board 10, the design requirements for the interconnection structures within the interconnection unit areas 10a can be reduced, and the process difficulty of forming the interconnection structures can be reduced, thereby enhancing the design flexibility and process flexibility of forming the intermediary board 10.

In the present embodiment, the plurality of interconnection unit areas 10a are arranged in an array. In other embodiments, based on actual design requirements, the plurality of interconnection unit areas may be arranged in other ways, such as staggered arrangement, etc.

It should be noted that in the present embodiment, for the convenience of illustration and explanation, only a portion of the interconnection unit area 10a is shown in the top view.

In the present embodiment, the material of the interconnection structure is a metallic material, for example, one or more of copper, aluminum, tungsten, cobalt, nickel, titanium, tantalum, titanium nitride, and tantalum nitride.

In the present embodiment, the intermediary board 10 including a redistribution structure board (e.g., RDL interposer) and the interconnection structure including one or more redistribution layers (RDLs) are taken as an example for illustration. By using the redistribution layer, the electrical connection ports of the device chip 20 can be redistributed, a larger number of pins can be supported, the circuit connection distance between the device chips becomes smaller, the density of the chip package is increased, and the width and spacing of the signal traces are significantly reduced, thereby increasing the density of the signals per unit area, and improving the performance of the circuits. Moreover, it is also possible to replace a part of the internal line design of the device chip 20 with the design of the redistribution layer, thereby reducing the design cost.

In the present embodiment, during the formation process of the packaging structure, the process of forming the intermediary board 10 includes forming an interconnection structure pattern in the interconnection unit area 10a. Forming the interconnection structure pattern includes the operation of sequentially performing an exposure treatment for each exposure window area 10b. The interconnection structure pattern is used to define a graphic of the interconnection structure.

In the present embodiment, during the formation process of the intermediary board 10, a photolithography process is used to form the interconnection structure pattern. For example, a step lithography process (Steppers: Step and repeat systems) is used to form the interconnection structure pattern. Thus, forming the interconnection structure pattern includes the operation of sequentially performing an exposure treatment for each exposure window area 10b.

For example, during each exposure process, only a local area (i.e., the exposure window area 10b) is exposed, and after the current exposure window area 10b has been exposed, the exposure process is moved to the next exposure window area 10b to repeat the exposure process until all the exposure window areas 10b have been exposed. Accordingly, in the present embodiment, the exposure window area 10b refers to the exposure field (reticle field) for each exposure process.

In some embodiments, each interconnection unit area 10a includes an exposure window area 10b, or each interconnection unit area 10a includes a plurality of connected exposure window areas 10b with overlapping areas between adjacent exposure window areas 10b.

In one example, when each interconnection unit area 10a includes a plurality of connected exposure window areas 10b, there is an overlapping area between the adjacent exposure window areas 10b. Thus, it is possible to stitch the adjacent exposure window areas 10b through the overlapping area. Through a plurality of consecutive exposures in the adjacent exposure window areas 10b, it is possible to obtain an exposure pattern of a larger dimensions and/or area, i.e., to obtain an interconnection structure pattern of a larger dimensions and/or area (e.g., an interconnection structure pattern of a larger length).

In the semiconductor field, the more times of stitching performed on the adjacent exposure window areas 10b, the higher the probability of an offset between the exposure patterns of the adjacent exposure window areas 10b. In the present embodiment, local interconnection of the intermediary board 10 is achieved through the interconnection unit areas 10a. The adjacent interconnection unit areas 10a are spaced apart from each other, and the electrical connection between the adjacent interconnection unit areas 10a is subsequently achieved through the interconnection chip, so as to achieve the global interconnection of the intermediary board 10. Accordingly, the times of stitching performed on the adjacent exposure window areas 10b can be reduced in the formation process of the intermediary board 10, which is conducive to reducing the requirements for the exposure process of forming the interconnection structure pattern, reducing the process difficulty of forming the interconnection structure pattern, and improving the exposure quality and the precision of the interconnection structure.

As an example, in the intermediary board 10, a portion of the interconnection unit area 10a includes an exposure window area 10b, and a portion of the interconnection unit area 10a includes a plurality of connected exposure window areas 10b. For example, in the present embodiment, a portion of the interconnection unit area 10a includes three connected exposure window areas 10b.

In some embodiments, the number of exposure window areas 10b included in the interconnection unit area 10a in the intermediary board 10 is determined based on actual design requirements.

As an example, each interconnection unit area 10a includes a plurality of connected exposure window areas 10b with overlapping areas between adjacent exposure window areas 10b. In each of the interconnection unit areas 10a, the plurality of exposure window areas 10b are arranged along a row direction (as shown in the X direction in FIG. 1), or the plurality of exposure window areas 10b are arranged along a column direction (as shown in the Y direction in FIG. 1). Or in each of the interconnection unit areas 10a, the plurality of exposure window areas 10b are arranged along the row direction and the column direction.

In another example, when the plurality of exposure window areas 10b are arranged along the row direction and/or the column direction, there are overlapping areas between each adjacent exposure window areas 10b arranged along the row direction and/or the column direction so as to stitch adjacent exposure windows 10b through the overlapping areas, thereby obtaining interconnection structural patterns of larger area and dimensions.

In the present embodiment, a plurality of connected exposure window areas 10b in the interconnection unit area 10a that are all arranged along the row direction are taken as an example for illustration.

It should be noted that in the case when each interconnection unit area 10a includes a plurality of exposure window areas 10b, the interconnection unit area 10a is opposite to the plurality of device chips 20 up and down, and electrical connection between the plurality of device chips 20 is achieved by utilizing the interconnection structure formed by the plurality of exposure window areas 10b.

In the case when each interconnection unit area 10a includes an exposure window area 10b, each the interconnection unit area 10a is opposite to one or more of the device chips 20 up and down, and the interconnection structure of each interconnection unit area 10a is configured to achieve electrical connections between the plurality of device chips 20.

The packaging structure further includes a packaging layer 30 disposed on the first bonding surface 101 of the intermediary board 10 and covering the sidewalls of the one or more device chips 20.

The packaging layer 30 is configured to achieve package integration between the one or more device chips 20 and the intermediary board 10. The packaging layer 30 can also play the role of insulation, scaling, and moisture-proof, which is conducive to improving package reliability.

As an embodiment, the material of the packaging layer 30 is a molding material, for example, epoxy resin. The epoxy resin has the advantages of low shrinkage, good adhesion, good corrosion resistance, excellent electrical properties, low cost, etc. In other embodiments, other suitable packaging materials may be selected for the packaging layer.

The one or more device chips 20 are bonded to the first bonding surface 101 for electrically connecting and packaging integration through the intermediary board 10 and the interconnection chip 50 to achieve specific functions.

In some embodiments, when the number of device chips 20 is more than one, the types of device chips 20 may be the same or different. For example, one of the device chips 20 may be a logic control chip, and another device chip 20 may be a memory chip.

The device chips 20 are electrically connected to the interconnection structure, and then the electrical connection between the device chips 20 can be achieved through the interconnection structure and the subsequent interconnection chips. For example, in the present embodiment, an interconnection end is formed on the device chip 20, and the interconnection end is electrically connected to the interconnection structure.

It should be noted that in the case when each interconnection unit area 10a includes a plurality of exposure window areas 10b, the interconnection unit area 10a is opposite to the plurality of device chips 20 up and down, and the electrical connection between the plurality of device chips 20 is achieved by utilizing the interconnection structure formed by the plurality of exposure window areas 10b.

In the case when each interconnection unit area 10a includes an exposure window area 10b, each the interconnection unit area 10a is opposite to one or more of the device chips 20 up and down, and the interconnection structure of each interconnection unit area 10a is configured to achieve an electrical connection between the plurality of device chips 20.

For example, the device chips 20 include opposed a first chip surface 201 and a second chip surface 202. The packaging structure further includes a first conductive structure 25 disposed between the second chip surface 202 and the first bonding surface 101 of the intermediary board 10.

Accordingly, in the present embodiment, the interconnection end is electrically connected to the first conductive structure 25 so as to achieve the electrical connection between the device chip 20 and the first conductive structure 25.

As an embodiment, the first conductive structure 25 is a conductive bump. In the present embodiment, the material of the first conductive structure 25 includes one or more of tin, copper, aluminum, tungsten, cobalt, nickel, titanium, tantalum, titanium nitride, and tantalum nitride. As an example, the material of the first conductive structure 25 is tin.

It should be noted that in the present embodiment, bonding between the device chip 20 and the first bonding surface 101 of the intermediary board 10 by the first conductive structure 25 is taken as an example for illustration. In other embodiments, the first conductive structure may also be omitted based on actual process requirements.

In the present embodiment, taking an example of the first chip surface 201 as a front side of the chip and the second chip surface 202 as a back side of the chip for illustration, the front side of the chip refers to the side that the device faces in the device chip 20, and the back side of the chip refers to the side facing away from the device in the device chip 20. In other embodiments, it may also be the case that the first chip surface is a back side of the chip, and the second chip surface is a front side of the chip.

In the present embodiment, the intermediary board 10 includes a plurality of interconnection unit areas 20a, with the adjacent interconnection unit areas 20a spaced apart from each other. One or more device chips 20 are bonded on the first bonding surface 101 of the intermediary board 10, and electrically connected to the interconnection structure. Interconnection chips 50 are bonded on the second bonding surface 102 of the intermediary board 10, and disposed between the adjacent interconnection unit areas 10a and electrically connected to the interconnection structure of the adjacent interconnection unit areas 10a, thereby achieving a global interconnection of the intermediary board 10 through the interconnection structure and the interconnection chips 50 and thus, enabling the electrical connection between the device chips 20, and also facilitating a reduction in the process requirements and process difficulty in forming the intermediary board 10, as well as enabling high density interconnection, optimizing the packaging process and packaging performance.

The interconnection chip 50 is used as a chip bridge (Bridge) for achieving interconnection between adjacent interconnection unit areas 10a. For example, in the present embodiment, the interconnection chip 50 is also disposed on a portion of the top of the interconnection structure in the adjacent interconnection unit area 10a to enable electrical connection between the interconnection chip 50 and the interconnection structure.

For example, one or more layers of interconnection wires (not shown in the figures) may be formed in the interconnection chip 50. The interconnection chip 50 may have external connection ends (not shown in the figures) formed on its surface, and the external connection ends may be electrically connected to the interconnection wires. For example, the number of external connection ends is at least two, which are electrically connected to the interconnection structure of the adjacent interconnection unit areas 10a, respectively. Thus, it can serve to connect adjacent interconnection unit areas 10a.

In the present embodiment, the material of the interconnection wires and the external connection ends is a metallic material, for example, one or more of copper, aluminum, tungsten, cobalt, nickel, titanium, tantalum, titanium nitride, and tantalum nitride.

In the present embodiment, the interconnection chip 50 includes a first interconnection chip 51 and a second interconnection chip 52. The first interconnection chip 51 is electrically connected to the interconnection structure of the adjacent interconnection unit areas 10a along the row direction, and the second interconnection chip 52 is electrically connected to the interconnection structure of the adjacent interconnection unit areas 10a along the column direction.

As an example, the number of the second interconnection chips 52 connecting the same adjacent interconnection unit area 10a is more than one, and each interconnection chip 52 is connected to the interconnection structure of the exposure window area 10b of the adjacent interconnection unit area 10a along the column direction, thereby increasing the density of interconnections of the adjacent interconnection unit area 10a. In other embodiments, the number of the second interconnection chips connected to the same neighboring interconnection unit area may also be only one.

In the present embodiment, the packaging structure further includes a second conductive structure 90 disposed between the interconnection chip 50 and the intermediary board 10. As an example, the second conductive structure 90 is a conductive bump.

In the present embodiment, the material of the second conductive structure 90 includes one or more of tin, copper, aluminum, tungsten, cobalt, nickel, titanium, tantalum, titanium nitride, and tantalum nitride. As an example, the material of the second conductive structure 90 is tin.

In the present embodiment, bonding between the second bonding surface 102 of the intermediary board 10 and the interconnection chip 50 by the second conductive structure 90 is taken as an example for illustration. In other embodiments, the second conductive structure may also be omitted based on actual process requirements.

In the present embodiment, the packaging structure further includes a power connector 80 bonded on the second bonding surface 102 of the intermediary board 10, and electrically connected to the interconnection structure. The packaging structure further includes an input/output connector 70 bonded on the second bonding surface 102 of the intermediary board 10, and electrically connected to the interconnection structure.

The power connector 80 is configured to achieve an electrical connection between the intermediary board 10 and a power module to achieve the power supply to the intermediary board 10, and the power supply to the device chip 20 through the intermediary board 10.

The input/output connector 70 is configured to achieve a connection between the intermediary board 10 and an external circuit.

As an example, the input/output connector 70 includes a Photonic Integrated Circuit connector (PIC), which enables optical (e.g., optical fiber) interconnection of relatively distant interconnection ports on the intermediary board 10, which is conducive to achieving the shortest circuit transmission path and information transmission path.

The packaging structure provided in the present embodiment may be formed by the packaging method of the embodiments of the present disclosure, may also be formed by other packaging methods.

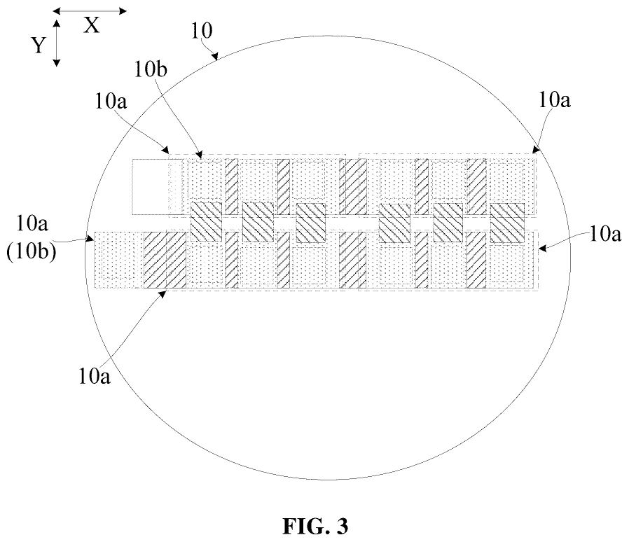

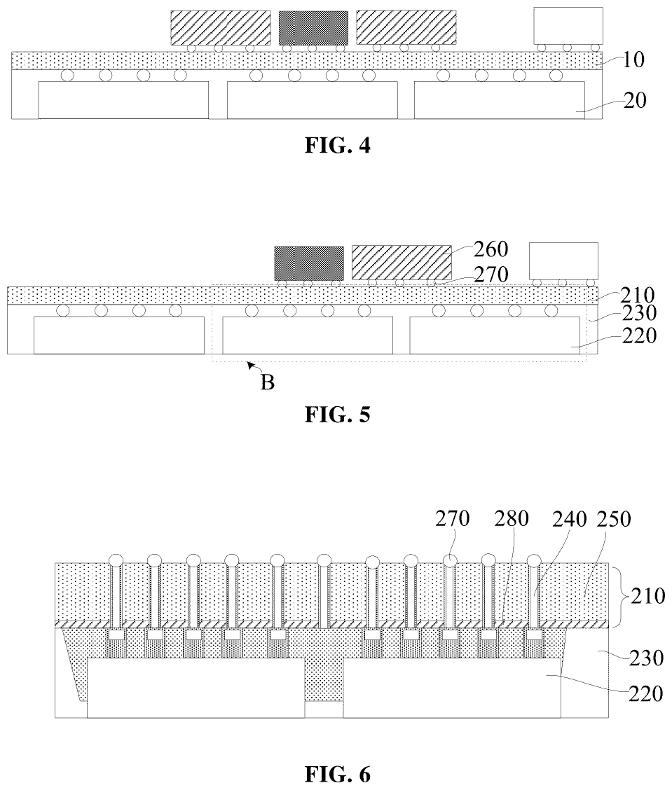

FIGS. 3 and 4 are structural schematic diagrams of another embodiment of the packaging structure of the present disclosure. FIG. 3 is a top view, and FIG. 4 is a cross-sectional view corresponding to FIG. 3. The similarities between the present embodiment and the previous embodiments will not be repeated herein, and the difference between the present embodiment and the previous embodiments is that each interconnection unit area 10a includes an exposure window area 10b.

In the present embodiment, in the case when each interconnection unit area 10a includes an exposure window area 10b, each the interconnection unit area 10a is opposite to one or more of the device chips 20 up and down; in the case when each interconnection unit area 10a is opposite to a plurality of device chips 20 up and down, the interconnection structure of each interconnection unit area 10a is used for achieving an electrical connection between a plurality of device chips 20.

The packaging structure provided in the present embodiment may be formed by the packaging method of the embodiments of the present disclosure, may also be formed by other packaging methods.

FIGS. 5 and 6 are structural schematic diagrams of yet another embodiment of the packaging structure of the present disclosure. FIG. 5 is a cross-sectional view, and FIG. 6 is a partially enlarged view of FIG. 5 at area B. The similarities between the present embodiment and the previous embodiments will not be repeated herein, and the differences between the present embodiment and the previous embodiments include the following.

In the present embodiment, the intermediary board 210 is an interposer, and the intermediary board 210 includes a substrate 250 and a backend interconnection structure layer (Backend Metal Layer) 280 disposed on the substrate 250. The interconnection structure is the backend interconnection structure layer 280. The backend interconnection structure layer 280 is configured to achieve an electrical connection between device chips 220.

As an example, the interposer is a silicon interposer, and the material of the substrate 250 is silicon. In other embodiments, the material of the substrate 250 may also be other semiconductor materials, or insulating materials based on actual process requirements.

The backend interconnection structure layer 280 is formed by a backend process. For example, in the present embodiment, a backend dielectric structure layer (not shown in the figures) may be formed on the substrate 250, and the backend interconnection structure layer 280 may be formed within the backend dielectric structure layer.

The material of the backend interconnection structure layer 280 is a metallic material, for example, one or more of copper, aluminum, tungsten, cobalt, nickel, titanium, tantalum, titanium nitride, and tantalum nitride.

In the present embodiment, the interposer further includes a through vias structure 240 penetrating the substrate 250, and the through vias structure 240 is electrically connected to the backend interconnection structure layer 280.

In the present embodiment, the interposer further includes a through vias structure 240 penetrating the substrate 250, and the through vias structure 240 is electrically connected to the backend interconnection structure layer 280.

The through vias structure 240 is electrically connected to the backend interconnection structure layer 280, thereby facilitating the electrical connection between the backend interconnection structure layers 280 of adjacent interconnection unit areas through the through vias structure 240 and the backend interconnection structure layer 280, and achieving electrical connection between the device chips 220.

For example, the interconnection chip 260 is electrically connected to the through vias structure 240 in the adjacent interconnection unit areas; or the interconnection chip 260 is electrically connected to the backend interconnection structure layer 280 in the adjacent interconnection unit areas.

In the present embodiment, the side of the interposer formed with the backend interconnection structure layer 280 faces the device chips 220, thereby shortening the interconnection distance between the backend interconnection structure layer 280 and the device chips 220. Accordingly, the interconnection chip 260 is electrically connected to the through vias structure 240 of the adjacent interconnection unit area so that the interconnection chip 260 achieves the electrical connection between the backend interconnection structure layer 280 of the adjacent device unit area through the through vias structure 240 of the adjacent interconnection unit area, and thus achieving electrical connection between the device chips 220 through the interconnection chip 260, the through vias structure 240, and the backend interconnection structure layer 280.

In other embodiments, when the side of the interposer formed with a backend interconnection structure layer faces away from the device chips, the interconnection chip is electrically connected to the backend interconnection structure layer of the adjacent interconnection unit area, and the device chips are electrically connected to the through vias structure. Thus, the interconnection chip is able to achieve an electrical connection between the device chips through the backend interconnection structure layer and the through vias structure.

In the present embodiment, the interposer is formed by a semiconductor manufacturing process, and the through vias structure 240 can have a higher density and a smaller pitch and dimensions, thereby increasing the interconnection density between the device chips 220.

In the present embodiment, the through vias structure 240 is a Through-Silicon Vias (TSV) structure. The TSV structure can reduce the interconnection length between the device chips 220 and the substrate 250 through vertical interconnections, which is conducive to reducing signal delay, reducing capacitance/inductance, achieving low-power consumption, high-speed communication, increasing broadband, and achieving miniaturization of device integration.

In the present embodiment, the material of the through vias structure 240 is a metallic material, for example, one or more of copper, aluminum, tungsten, cobalt, nickel, titanium, tantalum, titanium nitride, and tantalum nitride. As an example, the material of the through vias structure 240 is copper.

In the present embodiment, the packaging structure further includes a second conductive structure 270 disposed between the interconnection chip 260 and the intermediary board 210. The second conductive structure 270 is configured to achieve bonding between the interconnection chip 260 and the intermediary board 210. For example, the electrical connection between the interconnection chip 260 and the through vias structure 240 is achieved by the second conductive structure 270.

As an embodiment, the second conductive structure 270 is a conductive bump. In the present embodiment, the material of the second conductive structure 270 includes one or more of tin, copper, aluminum, tungsten, cobalt, nickel, titanium, tantalum, titanium nitride, and tantalum nitride. As an example, the material of the second conductive structure 270 is tin.

The packaging structure further includes a packaging layer 230 disposed on the first bonding surface of the intermediary board 210 and covering the sidewalls of the one or more device chips 220.

The packaging structure provided in the present embodiment may be formed by the packaging method of the embodiments of the present disclosure, may also be formed by other packaging methods.

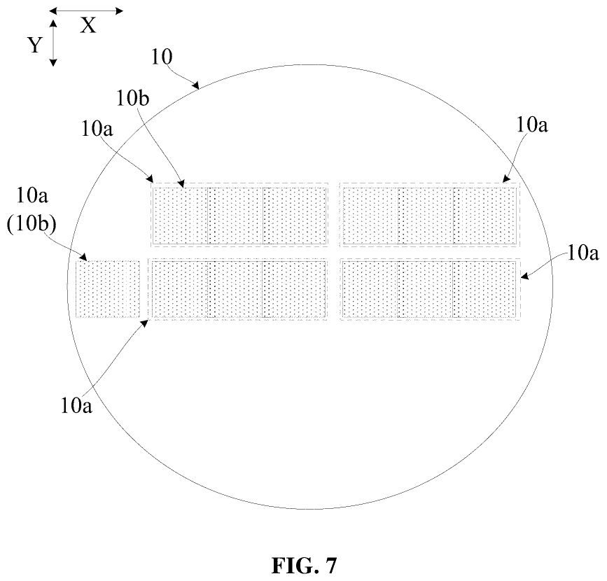

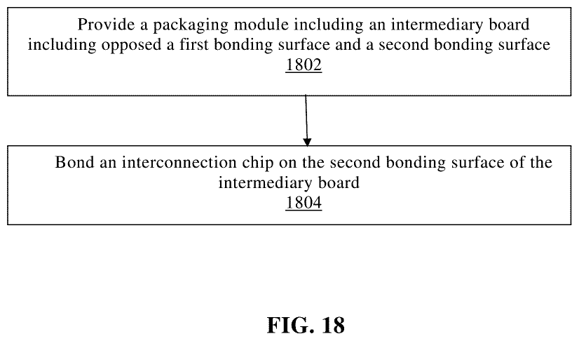

Accordingly, the present disclosure also provides a packaging method. FIGS. 7-13 are structural schematic diagrams corresponding to each operation in an embodiment of the packaging method of the present disclosure. FIG. 18 is a flowchart of a packaging method, according to some aspects of the present disclosure. The packaging method of the present embodiment is described below in detail in conjunction with the accompanying drawings.

Referring to FIGS. 7 and 18, a packaging module 100 is provided at operation 1802. The packaging module 100 includes an intermediary board 10, which includes opposed a first bonding surface 101 and a second bonding surface 102, as well as a plurality of interconnection unit areas 10a. The adjacent interconnection unit areas 10a are spaced apart from each other. An interconnection structure (not shown in the figures) may be formed within the interconnection unit areas 10a. The packaging module 100 also includes one or more device chips 20 bonded on the first bonding surface 101 of the intermediary board 10 and electrically connected to the interconnection structures.

The packaging module 100 is used for subsequent bonding of the interconnection chip so as to achieve package integration of the intermediary board 10, the device chips 20, and the interconnection chips.

The packaging module 100 includes the intermediary board 10 and the one or more device chips 20 so as to achieve package integration between the intermediary board 10 and the device chips 20.

In the present embodiment, by first providing the packaging module 100 and then bonding the interconnection chip on the packaging module 100, the intermediary board 10 and the device chips are first packaged and integrated, and the interconnection chip is bonded thereafter, which is conducive to improving the reliability of the package between the intermediary board 10 and the device chips 20.

The intermediary board 10 is configured to achieve the interconnection between the device chips 20. The interconnection between the device chips 20 is achieved through the intermediary board 10, which is conducive to shortening the interconnection distance between the device chips 20 and improving the efficiency and stability of information transmission.

The first bonding surface 101 is configured to bond one or more device chips 20, and the second bonding surface 102 is configured to subsequently bond interconnection chips.

The interconnection unit area 10a is configured to form an interconnection structure. For example, the interconnection structure is configured to achieve the interconnection between the device chips 20.

In the present embodiment, adjacent interconnection unit areas 10a are spaced apart from each other. That is, the interconnection structures within adjacent interconnection unit areas 10a are spaced apart from each other, and electrical connection between the interconnection structures of the adjacent interconnection unit areas 10a is subsequently achieved through the interconnection chip. Thus, in the process of forming the intermediary board 10, the design requirements for the interconnection structure within the interconnection unit area 10a can be reduced, and the process difficulty of forming the interconnection structure can be reduced, thereby enhancing the design flexibility and process flexibility of forming the intermediary board 10.

In the present embodiment, the plurality of interconnection unit areas 10a are arranged in an array. In other embodiments, based on actual design requirements, the plurality of interconnection unit areas may be arranged in other ways, for example, in a staggered arrangement.

It should be noted that in the present embodiment, only a portion of the interconnection unit area 10a is shown in the top view for the convenience of illustration and explanation.

In the present embodiment, the intermediary board 10 including a redistribution structure board (RDL interposer), and the interconnection structure including one or more redistribution layer (RDL) are taken as an example for illustration. By using the redistribution layer, the electrical connection ports of the device chip 20 can be redistributed, a larger number of pins can be supported, the circuit connection distance between the device chips becomes smaller, the density of the chip package is increased, and the width and spacing of the signal traces are significantly reduced, thereby increasing the density of the signals per unit area, and improving the performance of the circuits. Moreover, it is also possible to replace a part of the internal line design of the device chip 20 with the design of the redistribution layer, thereby reducing the design cost.

In the present embodiment, the material of the interconnection structure is a metallic material, for example, one or more of copper, aluminum, tungsten, cobalt, nickel, titanium, tantalum, titanium nitride, and tantalum nitride.

One or more device chips 20 are bonded to the first bonding surface 101 for electrical connection and package integration through the intermediary board 10 and subsequent interconnection chips to achieve specific functionality.

In some embodiments, when the number of device chips 20 is more than one, the types of device chips 20 may be the same or different. For example, one of the device chips 20 may be a logic control chip, and another of the device chips 20 may be a memory chip.

In the present embodiment, in the operation of providing the packaging module 100, the packaging module 100 further includes a packaging layer 30 formed on the first bonding surface 101 of the intermediary board 10 and covering the sidewalls of the one or more device chips 20.

The packaging layer 30 is configured to achieve package integration between one or more device chips 20 and the intermediary board 10, and the packaging layer 30 can also play the role of insulation, sealing, and moisture-proof, which is conducive to improving package reliability.

In an embodiment, the material of the packaging layer 30 is a molding material, for example, epoxy resin. The epoxy resin has the advantages of low shrinkage, good adhesion, good corrosion resistance, excellent electrical properties, and low cost. In other embodiments, other suitable package materials may be selected for the packaging layer.

Specific operations for providing the packaging module 100 are described in detail below in conjunction with the accompanying drawings.

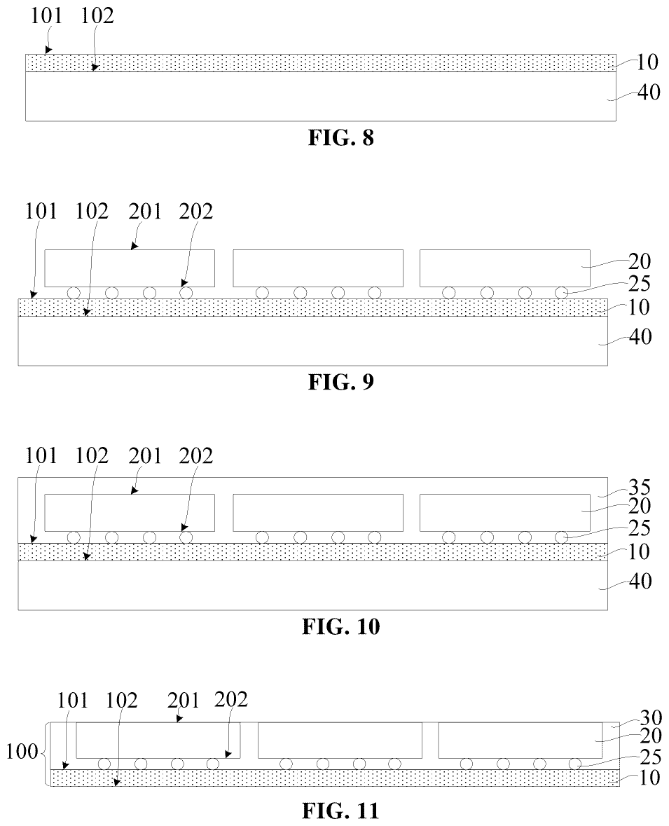

As shown in FIGS. 7 and 8, FIG. 7 is a top view, and FIG. 8 is a cross-sectional view of FIG. 7 at the interconnection unit area forming the intermediary board 10.

In the present embodiment, the operation of forming the intermediary board 10 includes forming an interconnection structure pattern in the interconnection unit area 10a, which includes the operation of sequentially performing exposure processing on each exposure window area 10b.

The interconnection structure pattern is used to define a graphic of the interconnection structure. In the present embodiment, a photolithography process is used to form the interconnection structure pattern.

For example, in the present embodiment, the interconnection structure pattern is formed using a step lithography process (Steppers: Step and repeat systems). Forming the interconnection structure pattern includes the operation of sequentially performing exposure processing on each exposure window area 10b.

By sequentially performing exposure processing on each exposure window area 10b to form an interconnection structure pattern, it is possible to improve the resolution of the formed interconnection structure pattern, i.e., to obtain an interconnection structure pattern of smaller dimensions and pitch.

In some embodiments, a step lithography machine (Stepper) is used to perform a step lithography process to form interconnection structure patterns. For example, during each exposure process, only a local area (i.e., exposure window area 10b) is exposed, and after the current exposure window area 10b has been exposed, the exposure process is moved to the next exposure window area 10b to repeat the exposure process until all exposure window areas 10b have been exposed.

Accordingly, in the present embodiment, the exposure window area 10b refers to the exposure reticle field of each exposure process.

In some embodiments, each interconnection unit area 10a includes an exposure window area 10b, or each interconnection unit area 10a includes a plurality of connected exposure window areas 10b with overlapping areas between adjacent exposure window areas 10b.

In the case when each interconnection unit area 10a includes a plurality of connected exposure window areas 10b, there is an overlapping area between adjacent exposure window areas 10b. Thus, it is possible to stitch the adjacent exposure window areas 10b through the overlapping area. And through a plurality of consecutive exposures in the adjacent exposure window areas 10b, it is possible to obtain an exposure pattern of a larger dimensions and/or area, i.e., to obtain an interconnection structure pattern of a larger dimensions and/or area (e.g., an interconnection structure pattern of a larger length).

In the semiconductor field, the more times of stitching performed on adjacent exposure window areas 10b, the higher the probability of offset between exposure patterns of adjacent exposure window areas 10b. In the present embodiment, the local interconnection of the intermediary board 10 is achieved through the interconnection unit area 10a, the adjacent interconnection unit areas 10a are spaced apart from each other, and the electrical connection between the adjacent interconnection unit areas 10a is subsequently achieved through the interconnection chips, so as to achieve a global interconnection of the intermediary board 10, accordingly, the times of stitching of the adjacent exposure window areas 10b can be reduced during the process of forming the intermediary board 10. Thus, it is beneficial for reducing the requirements of the exposure process for forming the interconnection structure pattern, accordingly reducing the process difficulty for forming the interconnection structure pattern, improving the quality of the exposure and the precision of the interconnection structure.

As an example, in the intermediary board 10, a portion of the interconnection unit area 10a includes an exposure window area 10b, and a portion of the interconnection unit area 10a includes a plurality of connected exposure window areas 10b. For example, in the present embodiment, a portion of the interconnection unit area 10a includes three connected exposure window areas 10b. In some embodiments, the number of exposure window areas 10b contained in the interconnection unit areas 10a in the intermediary board 10 is determined based on actual design requirements.

As an example, each interconnection unit area 10a includes a plurality of connected exposure window areas 10b with overlapping areas between adjacent exposure window areas 10b. In each of the interconnection unit areas 10a, the plurality of exposure window areas 10b are arranged along a row direction (as shown in the X direction in FIG. 7), or the plurality of exposure window areas 10b are arranged along a column direction (as shown in the Y direction in FIG. 7). Or in each of the interconnection unit areas 10a, the plurality of exposure window areas 10b are arranged along the row direction and the column direction.

When the plurality of exposure window areas 10b are arranged in the row direction and/or the column direction, there are overlapping areas between each adjacent exposure window areas 10b arranged in the row direction and/or the column direction so as to stitch the adjacent exposure windows 10b through the overlapping areas, thereby obtaining interconnection structural patterns of larger area and dimensions.

In the present embodiment, a plurality of connected exposure window areas 10b in the interconnection unit areas 10a that are all arranged along the row direction are taken as an example for illustration.

For example, in the present embodiment, the intermediary board 10 includes a redistribution board. The interconnection structure includes one or more redistribution layers. Accordingly, in the present embodiment, the operation of providing the intermediary board 10 includes forming one layer of redistribution layers, or sequentially forming a plurality of redistribution layers.

In the present embodiment, the operation of forming each of the redistribution layers includes forming a dielectric layer (not shown in the figures), forming interconnection through-holes (not shown in the figures) disposed in the dielectric layer in the interconnection unit areas 10a, the interconnection through-holes exposing the lower redistribution layer, forming a seed layer (not shown in the figures) on the bottom and sidewalls of the interconnection through-holes, and on the dielectric layer, forming a graphic definition layer on the seed layer (not shown in the figures), forming a plurality of interconnection openings in the graphic definition layer (not shown in the figures) disposed in the interconnection unit areas 10a, the interconnection openings exposing the seed layer located in the interconnection through-holes and the seed layer located on a portion of the top of the dielectric layer, forming a conductive layer (not shown in the figures) on the seed layer exposed by the interconnection openings, removing the graphic layer, and removing the seed layer exposed from the conductive layer. The remaining seed layer and the conductive layer disposed on the seed layer are used to form the redistribution layer.

The dielectric layer is configured to achieve isolation between the redistribution layers. The material of the dielectric layer is an insulating dielectric material, and in the present embodiment, the dielectric layer is also a photolithographable material, thereby facilitating the patterning of the dielectric layer to form the interconnection through-holes by means of a photolithographic process.

As an example, the material of the dielectric layer includes photosensitive polyimide (PI), photosensitive polybenzoxazole (PBO), or photosensitive benzocyclobutene (BCB). In the present embodiment, the material of the dielectric layer is photosensitive polyimide.

The interconnection through-holes expose the lower redistribution layer so that the formed redistribution layer can be electrically connected to the lower redistribution layer.

Accordingly, in the present embodiment, the operation of forming interconnection through-holes located in the interconnection unit areas 10a in the dielectric layer includes patterning the dielectric layer to form the interconnection through-holes using a photolithographic process.

The seed layer is used for the subsequent formation of the conductive layer and to improve the adhesive force between the conductive layer and the dielectric layer, to reduce the generation of voids in the conductive layer and to improve the conductivity of the redistribution layer. As an example, a sputtering (sputtering) process is used to form the seed layer.

The graphic definition layer is used to form the interconnection openings after subsequent patterning, in order to define the pattern of the interconnection structure. For example, the graphic definition layer is subsequently patterned by a photolithographic process, and the graphic definition layer is a photosensitive material. As an example, the material of the graphic definition layer is a photoresist.

The interconnection openings are used to form a pattern of interconnection structures, and are also used to provide spatial locations for forming the interconnection structures. For example, in the present embodiment, the interconnection openings are used to define a pattern for the subsequent conductive layer, and are also used to provide spatial locations for forming the conductive layer, thereby defining a pattern for the redistribution layer.

For example, the operation of forming a plurality of interconnection openings disposed in the interconnection unit areas 10a in the graphic definition layer includes using a photolithographic process to pattern the graphic definition layer to form a plurality of interconnection openings disposed in the interconnection unit area 10a in the graphic definition layer. The photolithographic process includes exposing the graphic definition layer of each exposure window area 10b n sequence.

Accordingly, after exposing the graphic definition layer of each exposure window area 10b is completed, the method further includes developing the graphic definition layer to form interconnection openings in the graphic definition layer.

The conductive layer is used to form a redistribution layer together with the seed layer. For example, an electrochemical coating process may be used to form the conductive layer. In other embodiments, a sputtering process may also be used to form the conductive layer.

In the present embodiment, the material of the graphic definition layer is photoresist. The process for removing the graphic definition layer may include one or two of a graying process and a wet photoresist removal process.

The seed layer exposed by the conductive layer is removed to achieve patterning of the redistribution layer. As an example, a wet etching process is used to remove the seed layer exposed by the conductive layer.

It should be noted that in the present embodiment, before forming the intermediary board 10, the method further includes providing a carrier substrate 40. Thus, the intermediary board 10 is formed on the carrier substrate 40.

For example, the carrier substrate 40 is used to provide support for forming the intermediary board 10, and also to provide an operating platform for subsequent processes.

In some embodiments, the carrier substrate 40 may be a carrier wafer, and the shape of the carrier wafer is circular. The carrier substrate 40 may also be a carrier panel (panel), and the shape of the carrier panel is square.

As shown in FIG. 9, one or more device chips 20 are bonded on the first bonding surface 101 of the intermediary board 10, and the device chips 20 are electrically connected to the interconnection structure.

The device chips 20 are electrically connected to the interconnection structure, and thus can achieve electrical connection between the device chips 20 through the interconnection structure and subsequent interconnection chips.

For example, in the present embodiment, an interconnection end is formed on the device chip 20, and the interconnection end is electrically connected to the interconnection structure.

It should be noted that in the case when each interconnection unit area 10a includes a plurality of exposure window areas 10b, the interconnection unit area 10a is opposite to the plurality of device chips 20 up and down, and electrical connection between the plurality of device chips 20 is achieved by utilizing the interconnection structure formed by the plurality of exposure window areas 10b.

In the case when each interconnection unit area 10a includes an exposure window area 10b, each of the interconnection unit areas 10a is opposite to one or more of the device chips 20 up and down, and in the case when each interconnection unit area 10a is opposite to a plurality of device chips 20 up and down, the interconnection structure of each interconnection unit area 10a is used for achieving an electrical connection between the plurality of device chips 20.

For example, the device chip 20 includes opposed a first chip surface 201 and a second chip surface 202. The operation of bonding one or more device chips 20 on the first bonding surface 101 of the intermediary board 10 includes achieving the bonding between the second chip surface 202 and the first bonding surface 101 of the intermediary board 10 by the first conductive structure 25.

Accordingly, in the present embodiment, the interconnection end is electrically connected to the first conductive structure 25 to achieve an electrical connection between the device chip 20 and the first conductive structure 25.

In the present embodiment, in one example, the first conductive structure 25 is formed on the first bonding surface 101 of the intermediary board 10 to achieve bonding between the second chip surface 202 and the first conductive structure 25. In another example, the first conductive structure 25 is formed on the second chip surface 202 to achieve bonding between the first conductive structure 25 and the first bonding surface 101 of the intermediary board 10. In still another example, a first sub-conductive structure (not shown in the figures) is formed on the first bonding surface 101 of the intermediary board 10, and a second sub-conductive structure (not shown in the figures) is formed on the second chip surface 202 to achieve bonding between the first sub-conductive structure and the second sub-conductive structure. The first sub-conductive structure and the second sub-conductive structure are used to form the first conductive structure 25.

As an embodiment, the first conductive structure 25 is a conductive bump. In the present embodiment, a bumping process is used to form the first conductive structure 25.

In the present embodiment, the material of the first conductive structure 25 includes one or more of tin, copper, aluminum, tungsten, cobalt, nickel, titanium, tantalum, titanium nitride, and tantalum nitride. As an example, the material of the first conductive structure 25 is tin.

It should be noted that in the present embodiment, achieving bonding between the device chip 20 and the first bonding surface 101 of the intermediary board 10 by the first conductive structure 25 is taken as an example for illustration. In other embodiments, the first conductive structure may also be omitted based on actual process requirements.

In the present embodiment, the first chip surface 201 as a front side of the chip and the second chip surface 202 as a back side of the chip are taken as an example for illustration. The front side of the chip refers to the side that the device faces in the device chip 20, and the back side of the chip refers to the side facing away from the device in the device chip 20.

Accordingly, in the present embodiment, Flip Chip technology is used to achieve the bonding between the device chip 20 and the intermediary board 10.

In other embodiments, it may also be the case that the first chip surface is the back side of the chip, and the second chip surface is the front side of the chip.

As shown in FIGS. 10 and 11, a packaging layer 30 covering the sidewalls of the one or more device chips 20 is formed on the first bonding surface 101 of the intermediary board 10.

In the present embodiment, the operation of forming the packaging layer 30 includes, as shown in FIG. 10, forming a packaging material layer 35 covering the one or more device chips 20 on the first bonding surface 101 of the intermediary board 10, as shown in FIG. 11, removing the packaging material layer 35 higher than the device chips 20, and exposing the side of the device chips 20 opposite to the intermediary board 10. The remaining packaging material layer 35 covering the packaging material layer 35 on the sidewalls of the device chip 20 is used as the packaging layer 30.

As an example, a molding process is used to form the packaging material layer 35. As an example, a grinding process is used to remove the packaging material layer 35 above the device chip 20.

It should be noted that in the present embodiment, the packaging layer 30 is only shown in a cross-sectional view for the convenience of illustration and explanation.

In the present embodiment, after forming the packaging material layer 35 and before removing the packaging material layer 35 above the device chip 20, the method further includes removing the carrier substrate.

In the present embodiment, after forming the intermediary board 10, the one or more device chips 20 are bonded on the first bonding surface 101 of the intermediary board 10, and the surface flatness of the intermediary board 10 is good, which is conducive to providing a flat surface and a high-quality bonding surface for bonding the device chips 20, thereby conducive to improving the bonding reliability of the device chips 20 on the first bonding surface 101 of the intermediary board 10, and also conducive to realization of a higher interconnection density between the intermediary board 10 and the device chips 20 (e.g., increasing the density of the first conductive structure 25). Furthermore, the device chips 20 are bonded after forming the intermediary board 10, which is conducive to testing the electrical properties of the device chips 20 before bonding the device chips 20, thereby conducive to improving the package yield.

It should be noted that in the present embodiment, the above operations of providing the packaging module are illustrated only as an example, and the operation of providing the packaging module is not limited to this.

For example, in other embodiments, the operation of providing the packaging module includes providing a carrier board, mounting one or more device chips on the carrier board, forming the intermediary board on the one or more device chips, and removing the carrier board.

Accordingly, in this embodiment, after mounting one or more device chips on the carrier board, and before forming the intermediary board, the method further includes forming a packaging layer covering the sidewalls of the device chips on the carrier board. The detailed description of the packaging layer can be referred to the corresponding description in the previous embodiment, which will not be repeated herein.

In this embodiment, the detailed operations of forming the intermediary board on one or more device chips can be referred to the corresponding description of the previous embodiments, which will not be repeated herein.

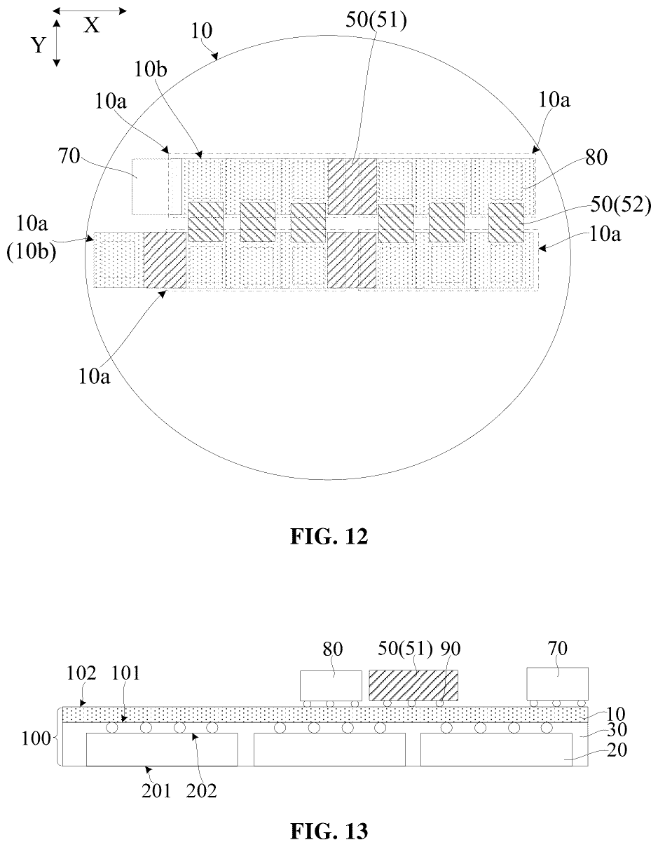

Referring to FIGS. 12, 13, and 18, FIG. 12 is a top view, and FIG. 13 is a cross-sectional view corresponding to FIG. 12. The interconnection chips 50 are bonded on the second bonding surface 102 of the intermediary board 10 at operation 1804. The interconnection chips 50 are disposed on the intermediary board 10 between the adjacent interconnection unit areas 10a and electrically connected with the interconnection structures of the adjacent interconnection unit areas 10a.

In the present embodiment, the packaging module 100 includes an intermediary board 10 and one or more device chips 20. The intermediary board 10 includes a plurality of interconnection unit areas 20a, and the adjacent interconnection unit areas 10a are spaced apart from each other. One or more device chips 20 are bonded on a first bonding surface 101 of the intermediary board 10, and the device chips 20 are electrically connected to the interconnection structure. Moreover, the interconnection chips 50 are bonded on the second bonding surface 102 of the intermediary board 10, and the interconnection chips 50 are disposed between the adjacent interconnection unit areas 10a and electrically connected to the interconnection structure of the adjacent interconnection unit area 10a, thereby achieving global interconnection of the intermediary board 10 by the interconnection structure and the interconnection chip 50, and thus enabling the electrical connection between the device chips 20, and facilitating a reduction in the process requirements and process difficulty of forming the intermediary board 10, as well as enabling high-density interconnections and optimizing the packaging process and packaging performance.

The interconnection chip 50 is used as a chip bridge (Bridge) for achieving interconnections between the adjacent interconnection unit areas 10a. For example, in the present embodiment, the interconnection chip 50 is also disposed on a portion of the top of the interconnection structure in the adjacent interconnection unit areas 10a to achieve an electrical connection between the interconnection chip 50 and the interconnection structure.

For example, one or more layers of interconnection wires (not shown in the figures) may be formed in the interconnection chip 50, and the interconnection chip 50 may have external connection ends (not shown in the figures) formed on its surface, and the external connection ends may be electrically connected to the interconnection wires. For example, the number of the external connection ends is at least two, electrically connected to the interconnection structure of the adjacent interconnection unit areas 10a, respectively. Thus, it can serve to connect adjacent interconnection unit areas 10a.

In the present embodiment, the material of the interconnection wires and the external connection ends is a metallic material, for example, one or more of copper, aluminum, tungsten, cobalt, nickel, titanium, tantalum, titanium nitride, and tantalum nitride.

In the present embodiment, in the operation of bonding an interconnection chip 50 on the second bonding surface 102 of the intermediary board 10, the interconnection chip 50 includes a first interconnection chip 51 and a second interconnection chip 52, the first interconnection chip 51 is electrically connected to the interconnection structures of the adjacent interconnection unit areas 10a in the row direction, and the second interconnection chip 52 is electrically connected to the interconnection structures of the adjacent interconnection unit areas 10a in the column direction.

As an example, the number of the second interconnection chips 52 connecting the same adjacent interconnection unit area 10a is more than one, and each interconnection chip 52 is connected to an interconnection structure of the exposure window area 10b of the adjacent interconnection unit area 10a along the column direction, thereby increasing the interconnection density of the adjacent interconnection unit area 10a. In other embodiments, the number of the second interconnection chip connected to the same adjacent interconnection unit area may also be only one.

In the present embodiment, the operation of bonding the interconnection chip 50 on the second bonding surface 102 of the intermediary board 10 includes achieving bonding between the interconnection chip 50 and the intermediary board 10 by the second conductive structure 90.

For example, a second conductive structure 90 is formed on the second bonding surface 102 of the intermediary board 10, achieving bonding between the second conductive structure 90 and the interconnection chip 50. Or a second conductive structure 90 is formed on the interconnection chip 50, achieving bonding between the second conductive structure 90 and the second bonding surface 102 of the intermediary board 10. Or a third sub-conductive structure (not shown in the figures) may be formed on the second bonding surface 102 of the intermediary board 10. Or a fourth sub-conductive structure is formed on the interconnection chip 50, achieving bonding between the third sub-conductive structure and the fourth sub-conductive structure. The third sub-conductive structure and the fourth sub-conductive structure are used to form the second conductive structure.

As an embodiment, the second conductive structure 90 is a conductive bump. In the present embodiment, a bumping process is used to form the second conductive structure 90.

In the present embodiment, the material of the second conductive structure 90 includes one or more of tin, copper, aluminum, tungsten, cobalt, nickel, titanium, tantalum, titanium nitride, and tantalum nitride. As an example, the material of the second conductive structure 90 is tin.

In the present embodiment, bonding between the second bonding surface 102 of the intermediary board 10 and the interconnection chip 50 by the second conductive structure 90 is taken as an example for illustration. In other embodiments, the second conductive structure may also be omitted based on actual process requirements.

It should be noted that in the present embodiment, the packaging method further includes bonding, on the second bonding surface 102 of the intermediary board 10, a power connector 80 that is electrically connected to the interconnection structure, and bonding, on the second bonding surface 102 of the intermediary board 10, an input/output connector 70 that is electrically connected to the interconnection structure.

The power connector 80 is configured to achieve an electrical connection between the intermediary board 10 and the power module, to achieve the power supply to the intermediary board 10, and thus achieve the power supply to the device chip 20 through the intermediary board 10.

The input/output connector 70 is configured to achieve an electrical connection between the intermediary board 10 and the external circuit. As an example, the input/output connector 70 includes a Photonic Integrated Circuit connector (PIC), which enables optical (e.g., optical fiber) interconnection of relatively distant interconnection ports on the intermediary board 10, which is conducive to achieving the shortest circuit transmission path and information transmission path.

It should be noted that, in some embodiments, the interconnection unit area 10a may include a first area (not labeled) for bonding the interconnection chip 50 and a second area (not labeled) for bonding the connectors (e.g., the power connector and input/output connector). The interconnection density of the first area is higher than the interconnection density of the second area.

In some embodiments, in the process of forming the interconnection structure pattern in the first area, the interconnection structure pattern is formed by exposing the plurality of exposure window areas 10b in sequence. For example, a step lithography machine is used to sequentially perform exposure processing in the first area to form the interconnection structure pattern.

In some embodiments, in the process of forming the interconnection structure pattern in the second area, a global exposure is used to perform a one-time exposure process in the second area to form an interconnect structure pattern in the second area. For example, a mask aligner is used to perform the global exposure process.

In the present embodiment, the interconnection density of the first area is higher than the interconnection density of the second area, and by using different exposure methods in areas with different interconnection densities, it is possible to achieve higher exposure quality in areas with higher interconnection densities while saving time, and conducive to improving production capacity.

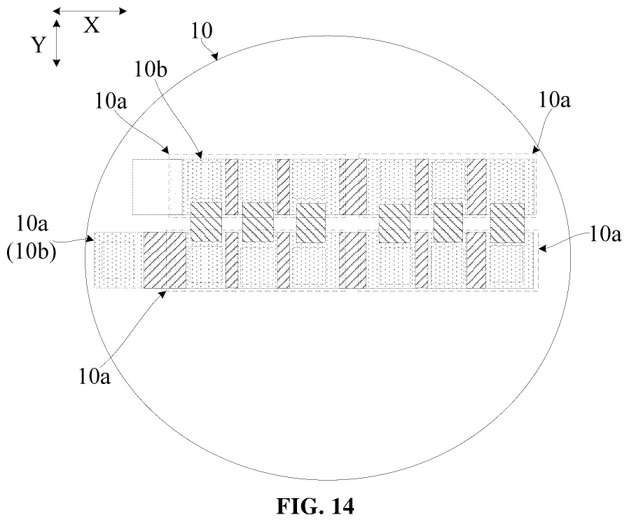

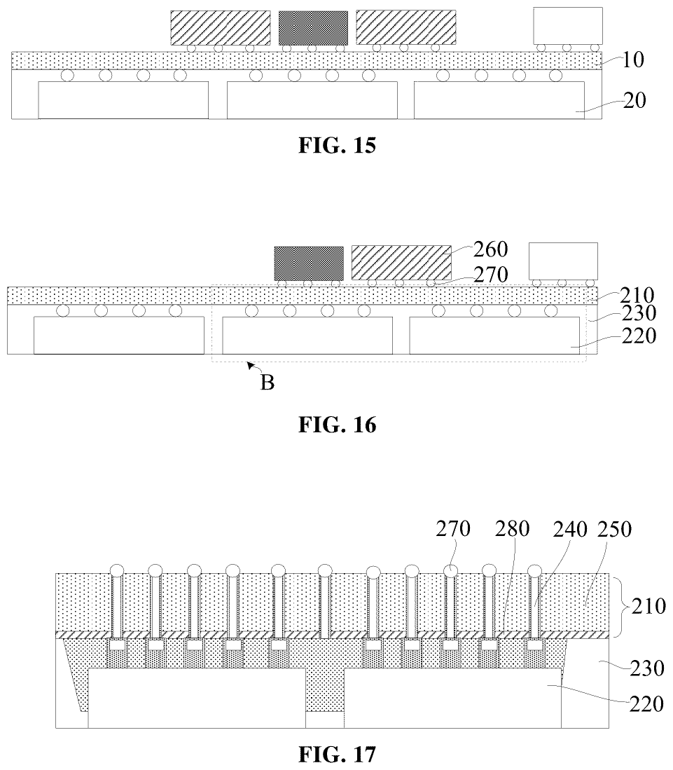

FIGS. 14 and 15 are structural schematic diagrams corresponding to each operation in another embodiment of the packaging method of the present disclosure. FIG. 14 is a top view, and FIG. 15 is a cross-sectional view corresponding to FIG. 14. The similarities between the present embodiment and the previous embodiments will not be repeated herein, and the differences between the present embodiment and the previous embodiments are:

Each interconnection unit area 10a includes an exposure window area 10b. In the present embodiment, in the case when each interconnection unit area 10a includes an exposure window area 10b, each of the interconnection unit areas 10a is opposite to one or more of the device chips 20 up and down, and the interconnection structure of each interconnection unit area 10a is used for achieving an electrical connection between a plurality of device chips 20.

FIGS. 16 and 17 are schematic diagrams of the structures corresponding to the various operations in yet another embodiment of the packaging method of the present disclosure. FIG. 16 is a cross-sectional view, and FIG. 17 is a partially enlarged view of FIG. 16 at area B. The similarities between the present embodiment and the previous embodiments will not be repeated herein, and the differences between the present embodiment and the previous embodiments are:

In the present embodiment, the intermediary board 210 is an interposer, and the intermediary board 210 includes a substrate 250 and a backend interconnection structure layer (Backend Metal Layer) 280 disposed on the substrate 250. The interconnection structure is the backend interconnection structure layer 280. The backend interconnection structure layer 280 is used for achieving an electrical connection between device chips 220.

As an example, the interposer is a silicon interposer, and the material of the substrate 250 is silicon. In other embodiments, the material of the substrate may also be other semiconductor materials or insulating materials based on actual process requirements.

The backend interconnection structure layer 280 is formed by a backend process. For example, in the present embodiment, a backend dielectric structure layer (not shown in the figures) is formed on the substrate 250, and the backend interconnection structure layer 280 is formed within the backend dielectric structure layer.

The material of the backend interconnection structure layer 280 is a metallic material, for example, one or more of copper, aluminum, tungsten, cobalt, nickel, titanium, tantalum, titanium nitride, and tantalum nitride.

In the present embodiment, the interposer further includes a through vias structure 240 penetrating the substrate 250, and the through vias structure 240 is electrically connected to the backend interconnection structure layer 280.

The through vias structure 240 is electrically connected to the backend interconnection structure layer, thereby enabling electrical connection between the backend interconnection structure layers 280 of the adjacent interconnection unit areas through the through vias structure 240 and the backend interconnection structure layer 280, and thus achieving electrical connection between the device chips 220.

For example, the interconnection chip 260 is electrically connected to the through vias structure 240 of the adjacent the interconnection unit areas, or the interconnection chip 260 is electrically connected to the backend interconnection structure layer 280 of the adjacent the interconnection unit areas.

In the present embodiment, the side of the interposer formed with the backend interconnection structure layer 280 faces the device chips 220, thereby shortening the interconnection distance between the backend interconnection structure layer 280 and the device chips 220. Accordingly, the interconnection chip 260 is electrically connected to the through vias structure 240 of the adjacent interconnection unit area so that the interconnection chip 260 achieves the electrical connection between the backend interconnection structure layer 280 of the adjacent device unit area through the through vias structure 240 of the adjacent interconnection unit area. Thus, the electrical connection between the device chips 220 is achieved through the interconnection chip 260, the through vias structure 240, and the backend interconnection structure layer 280.

In other embodiments, when the side of the interposer formed with a backend interconnection structure layer faces away from the device chips, the interconnection chip is electrically connected to the backend interconnection structure layer of the adjacent interconnection unit area, and the device chips are electrically connected to the through vias structure, such that the interconnection chip is able to achieve electrical connection between the device chips through the backend interconnection structure layer and the through vias structure.

In the present embodiment, the operation of forming the intermediary board 210 includes providing a substrate 250 and the backend interconnection structure layer 280, forming a plurality of through vias structures 240, penetrating the thickness of a portion of the substrate 250, where the through vias structures 240 are in contact with the backend interconnection structure layer 280, and removing the substrate 250 higher than the end of the through vias structures 240 to expose the through vias structures 240.

In the present embodiment, the interposer is formed by a semiconductor manufacturing process, and the through vias structure 240 can have a higher density and a smaller pitch and dimensions, thereby increasing the interconnection density between the device chips 220.

In the present embodiment, the through vias structure 240 is a Through-Silicon Vias (TSV) structure. The TSV structure can reduce the interconnection length between the device chips 220 and the substrate 250 through vertical interconnections, which is conducive to reducing signal delay, reducing capacitance/inductance, achieving low-power consumption, high-speed communication, increasing broadband, and achieving miniaturization of device integration.

In the present embodiment, the material of the through vias structure 240 is a metallic material, for example, one or more of copper, aluminum, tungsten, cobalt, nickel, titanium, tantalum, titanium nitride, and tantalum nitride. As an example, the material of the through vias structure 240 is copper.

In the present embodiment, the operation of bonding the interconnection chip 260 on the second bonding surface of the intermediary board 210 includes achieving the bonding between the interconnection chip 260 and the intermediary board 210 through the second conductive structure 270. For example, an electrical connection between the interconnection chip 260 and the through vias structure 240 is achieved by the second conductive structure 270.

As an embodiment, the second conductive structure 270 is a conductive bump. In the present embodiment, the material of the second conductive structure 270 includes one or more of tin, copper, aluminum, tungsten, cobalt, nickel, titanium, tantalum, titanium nitride, and tantalum nitride. As an example, the material of the second conductive structure 270 is tin.

The foregoing description of the specific embodiments can be readily modified and/or adapted for various applications. Therefore, such adaptations and modifications are intended to be within the meaning and range of equivalents of the disclosed embodiments, based on the teaching and guidance presented herein. The breadth and scope of the present disclosure should not be limited by any of the above-described embodiments, but should be defined only in accordance with the following claims and their equivalents.

What is claimed is:

1. A packaging structure, comprising:
an intermediary board comprising opposed a first bonding surface and a second bonding surface, the intermediary board comprising a plurality of interconnection unit areas, adjacent interconnection unit areas being spaced apart from each other, and an interconnection structure being formed within the interconnection unit area;
one or more device chips bonded on the first bonding surface of the intermediary board, the device chips being electrically connected to the interconnection structures; and
an interconnection chip bonded on the second bonding surface of the intermediary board, the interconnection chip being disposed on the intermediary board between the adjacent interconnection unit areas and electrically connected to the interconnection structures of the adjacent interconnection unit areas.

2. The packaging structure according to claim 1, wherein each interconnection unit area comprises an exposure window area, or a plurality of connected exposure window areas with an overlapping area being between adjacent exposure window areas.

3. The packaging structure according to claim 2, wherein
the plurality of interconnection unit areas are arranged in an array pattern;
each interconnection unit area comprises a plurality of connected exposure window areas with an overlapping area between adjacent exposure window areas; and
in each interconnection unit area, the plurality of exposure window areas are arranged along a row direction, along a column direction, or along a row direction and a column direction.

4. The packaging structure according to claim 1, wherein
each interconnection unit area comprises an exposure window area; and
each interconnection unit area is opposite to one or more of the device chips up and down, and the interconnection structure of each interconnection unit area is configured to achieve an electrical connection between the device chips.

5. The packaging structure according to claim 1, wherein
the intermediary board is a redistribution structure board; and
the interconnection structure comprises one or more redistribution layers.

6. The packaging structure according to claim 1, wherein
the intermediary board is an interposer comprising a substrate and a backend interconnection structure layer disposed on the substrate;
the interconnection structure is the backend interconnection structure layer;
the interposer further comprises a through vias structure penetrating the substrate, the through vias structure being electrically connected to the backend interconnection structure layer; and
the interconnection chip is electrically connected to the through vias structures of the adjacent interconnection unit areas, or the backend interconnection structure layer of the adjacent interconnection unit areas.

7. The packaging structure according to claim 1, wherein
the plurality of interconnection unit areas are arranged in an array pattern; and
the interconnection chip comprises a first interconnection chip and a second interconnection chip, the first interconnection chip being electrically connected to the interconnection structures of the adjacent interconnection unit areas along a row direction, the second interconnection chip being electrically connected to the interconnection structures of the adjacent interconnection unit areas along a column direction.

8. The packaging structure according to claim 1, further comprising:
a power connector bonded on the second bonding surface of the intermediary board, the power connector being electrically connected to the interconnection structure; and
an input/output connector bonded to the second bonding surface of the intermediary board, the input/output connector being electrically connected to the interconnection structure.

9. A packaging method, comprising:
providing a packaging module, the packaging module comprising:
an intermediary board comprising opposed a first bonding surface and a second bonding surface, the intermediary board comprising a plurality of interconnection unit areas, adjacent interconnection unit areas being spaced apart from each other, and an interconnection structure being formed within the interconnection unit area; and
one or more device chips bonded on the first bonding surface of the intermediary board and electrically connected to the interconnection structures; and
bonding an interconnection chip on the second bonding surface of the intermediary board, the interconnection chip being disposed on the intermediary board between the adjacent interconnection unit areas and electrically connected to the interconnection structures of the interconnection unit areas.

10. The packaging method according to claim 9, wherein providing the packaging module comprises:
forming the intermediary board; and
bonding one or more device chips, the device chip being electrically connected to the interconnection structure on the first bonding surface of the intermediary board; or
providing a carrier board;
attaching one or more device chips on the carrier board;
forming the intermediary board on the one or more device chips; and
removing the carrier board.

11. The packaging method according to claim 10, wherein
forming the intermediary board comprises forming an interconnection structure pattern in the interconnection unit area;
forming the interconnection structure pattern comprises performing an exposure process on each exposure window area in turn; and
each interconnection unit area comprises an exposure window area, or a plurality of connected exposure window areas with an overlapping area being between adjacent exposure window areas.

12. The packaging method according to claim 11, wherein
the plurality of interconnection unit areas are arranged in an array pattern;
each interconnection unit area comprises a plurality of connected exposure window areas with an overlapping area between adjacent exposure window areas; and
in each interconnection unit area, the plurality of exposure window areas are arranged along a row direction, along a column direction, or along a row direction and a column direction.

13. The packaging method according to claim 11, wherein
each interconnection unit area comprises an exposure window area; and
after bonding one or more device chips on the first bonding surface of the intermediary board, each interconnection unit area is opposite to one or more of the device chips up and down, and the interconnection structure of each interconnection unit area is configured to achieve an electrical connection between the device chips.

14. The packaging method according to claim 9, wherein
the intermediary board comprises a redistribution structure board; and
the interconnection structure comprises one or more redistribution layers.

15. The packaging method according to claim 14, wherein
providing the packaging module comprises forming the intermediary board;
forming the intermediary board comprises forming one redistribution layer, or a plurality of redistribution layers in turn; and
forming each of the redistribution layers comprises:
forming a dielectric layer;
forming, in the dielectric layer, interconnection through-vias disposed in the interconnection unit area, the interconnection through-vias exposing the redistribution layer;
forming a seed layer on bottoms and sidewalls of the interconnection through-vias, and on the dielectric layer;
forming a graphic definition layer on the seed layer;
forming, in the graphic definition layer, a plurality of interconnection openings disposed in the interconnection unit area, the interconnection openings exposing the seed layer disposed within the interconnection through-vias and the seed layer disposed on a top of a portion of the dielectric layer;
forming a conductive layer on the seed layer exposed by the interconnection openings;
removing the graphic definition layer; and
removing the seed layer exposed from the conductive layer, the remaining seed layer and the conductive layer disposed on the seed layer are configured to form the redistribution layer.

16. The packaging method according to claim 15, wherein
each interconnection unit area comprises an exposure window area, or a plurality of connected exposure window areas with an overlapping area being between adjacent exposure window areas; and
forming, in the graphic definition layer, the plurality of interconnection openings disposed in the interconnection unit area comprises:
using a photolithographic process to pattern the graphic definition layer; and
forming, in the graphic definition layer, a plurality of interconnection openings disposed in the interconnection unit area, the photolithographic process comprises exposing the graphic definition layer of each exposure window area in turn.

17. The packaging method according to claim 9, wherein
the intermediary board is an interposer comprising a substrate and a backend interconnection structure layer disposed on the substrate;
the interconnection structure is the backend interconnection structure layer;
the interposer further comprises a through vias structure penetrating the substrate, the through vias structure being electrically connected to the backend interconnection structure layer; and
the interconnection chip is electrically connected to the through vias structure of the adjacent interconnection unit areas, or the backend interconnection structure layer of the adjacent interconnection unit areas.

18. The packaging method according to claim 9, wherein
the plurality of interconnection unit areas are arranged in an array pattern; and
in bonding the interconnection chip on the second bonding surface of the intermediary board, the interconnection chip comprises a first interconnection chip and a second interconnection chip, the first interconnection chip being electrically connected to the interconnection structures of the adjacent interconnection unit areas along a row direction, and the second interconnection chip being electrically connected to the interconnection structures of the adjacent interconnection unit areas along a column direction.

19. The packaging method according to claim 9, wherein in providing the packaging module, the packaging module further comprises a packaging layer formed on the first bonding surface of the intermediary board and covering a sidewall of the one or more device chips.

20. The packaging method according to claim 9, further comprising:
bonding a power connector on the second bonding surface of the intermediary board, the power connector being electrically connected to the interconnection structure; and
bonding an input/output connector on the second bonding surface of the intermediary board, the input/output connector being electrically connected to the interconnection structure.
